(19) United States
(12) Patent Application Publication
(10) Pub. No.: US 2007/0238310 A1
(43) Pub. Date: Oct. 11, 2007

(54) METHOD FOR MANUFACTURING A SEMICONDUCTOR DEVICE HAVING A SILICON OXYNITRIDE FILM

(75) Inventors: Yo Matsuda, Tokyo (JP); Fumiki Aiso, Tokyo (JP); Toshiyuki Hirota, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/697,082

(22) Filed: Apr. 5, 2007

(30) Foreign Application Priority Data
Apr. 6, 2006 (JP) 2006-104860

(51) Int. Cl. H01L 21/31

(52) U.S. Cl. 438/758

(57) ABSTRACT

A semiconductor device manufacturing method includes: a process of forming an isolation trench on the surface of a semiconductor substrate; a process of forming a thermally-oxidized film on the surface of the isolation trench; a process of depositing a silicon oxynitride film on the semiconductor substrate via the thermally-oxidized film; a process of heat-treating the silicon oxynitride film in an oxidizing atmosphere; and a process of etching the top of the thermally-oxidized film and the heat-treated silicon oxynitride film.

### BACKGROUND OF THE INVENTION

1. Field of the Invention

The present invention relates to a method for manufacturing a semiconductor device having a silicon oxynitride film. More specifically, the present invention relates to a technique that forms an insulating film on a semiconductor substrate and is suitably applied to forming an element isolation structure on the semiconductor substrate.

2. Description of the Related Art

A shallow trench isolation structure, generally referred to as an STI structure and hereinafter as an isolation structure, is formed on the surface of a semiconductor substrate for isolating semiconductor elements, e.g., memory cells, from one another. The isolation structure includes a trench formed on the surface of the semiconductor substrate and an insulating layer formed inside the trench. The STI structure is described in Patent Publication JP-A-1999-233614A, for example. FIGS. 6A to 6C are sectional views of a semiconductor device, consecutively showing steps of a conventional process for forming the isolation structure.

As shown in FIG. 6A, a mask 44 is formed on the semiconductor substrate 41 made of silicon, to cover element formation regions 40A where a semiconductor element is formed. The mask 44 is formed as a multilayer film including a silicon oxide layer 42 and a silicon nitride layer 43. Dry etching is performed to form an isolation trench 45 on a surface portion of the semiconductor substrate 41 exposed from the mask 44. A thermal oxidation process is then used to form a silicon oxide film, i.e., thermally-oxidized film 46, on the entire surface of the semiconductor substrate 41 including the internal of the isolation trench 45.

A high-density-plasma (HDP) CVD process is used to deposit a silicon oxide film 47 on the entire surface including the internal of the isolation trench 45 (FIG. 6B). CMP process, wet etching process, and the like are used to planarize the surface and remove the silicon oxide film 47, thermally-oxidized film 46, and mask 44 until the semiconductor substrate 41 is exposed. As shown in FIG. 6C, the isolation structure is formed so that the isolation region 40B includes the isolation trench 45 and the insulating films 46 and 47 embedded in the isolation trench 45.

When the silicon oxide film 47 is deposited in the isolation trench 45, a hollow such as a seam or a void may be generated in the film. A conductive material may enter the hollow in the subsequent process and cause the semiconductor device to malfunction. The use of the HDP-CVD process can deposit a high-density film and prevent the hollow from being generated in the silicon oxide film.

Along with a higher integration in the current semiconductor device, a finer pattern for the isolation region is used and the aspect ratio of the isolation region is increasing. For example, a next-generation semiconductor device requires an isolation structure having an aspect ratio of 3.1 or more, such as a trench width of 80 nm or less with the trench depth being 250 nm or more. Even the use of the HDP-CVD process may generate the above-described void in the isolation structure that has a trench width of 80 nm or less and an aspect ratio of 3.1 or more.

The HDP-CVD process is known to provide a film growth and a directional sputtering simultaneously. As shown in FIG. 6B, a tilt on the side of the mask 44 differs from the tilt on the side of the isolation trench 45. A void is generated in the silicon oxide film because the boundary 48 between both the sides is not fully sputtered. A possible solution is to increase a sputtering energy so that the boundary 48 is fully sputtered. However, this damages the surface of the semiconductor substrate 41 and may cause a junction leak current across the PN junction of the semiconductor element.

It is necessary to suppress occurring of the void and prevent a conductive material from entering the void for the purpose of improving the product yield in a process for manufacturing the semiconductor device.

### SUMMARY OF THE INVENTION

It is therefore an object of the present invention to provide a method for manufacturing a semiconductor device, which is capable of preventing the void from occurring in an insulating film without damaging the semiconductor substrate surface during formation of the fine isolation structure, for example.

The present invention provides a method for forming a semiconductor device, including the steps of: depositing a silicon oxynitride film overlying a semiconductor substrate; heat treating the silicon oxynitride film in an oxidizing atmosphere; and etching the silicon oxynitride film for patterning after the heat treating.

In accordance with the method of the present invention, the silicon oxynitride film having a superior filling property allows the underlying structure to be embedded substantially without occurrence of a void in the silicon oxynitride film and damage on the semiconductor substrate. In addition, the silicon oxynitride film subjected to the heat treatment in the oxidizing atmosphere has a smaller nitrogen concentration and thus has a modified etch rate approximating to the etch rate of a silicon oxide film in the etching step. The modified etch rate provides a suitable etching performance in the process for manufacturing the semiconductor device.

The above and other objects, features and advantages of the present invention will be more apparent from the following description, referring to the accompanying drawings.

### BRIEF DESCRIPTION OF THE DRAWINGS

FIGS. 1A to 1L are sectional views of a semiconductor device, consecutively showing steps of a process for manufacturing the semiconductor device according to a first embodiment of the present invention;

FIG. 2 is a flowchart showing the deposition process of the silicon oxynitride film in the first embodiment;

FIG. 3 is a flowchart showing a heat treatment process conducted for the silicon oxynitride film;

FIG. 4 is a graph showing composition ratios of the silicon oxynitride film before and after the heat treatment;

FIGS. 5A to 5K are sectional views of a semiconductor device, consecutively showing steps of a process for manufacturing the semiconductor device according to a second embodiment of the present invention; and

FIGS. 6A to 6C are sectional views of a semiconductor device, consecutively showing steps of a conventional process for manufacturing the semiconductor device.

### DETAILED DESCRIPTION OF THE PREFERRED EMBODIMENTS

Embodiments of the present invention will be described in further detail with reference to the accompanying drawings. In one example, the process of the present invention is directed to forming an isolation structure including a plurality of isolation trenches having different widths.

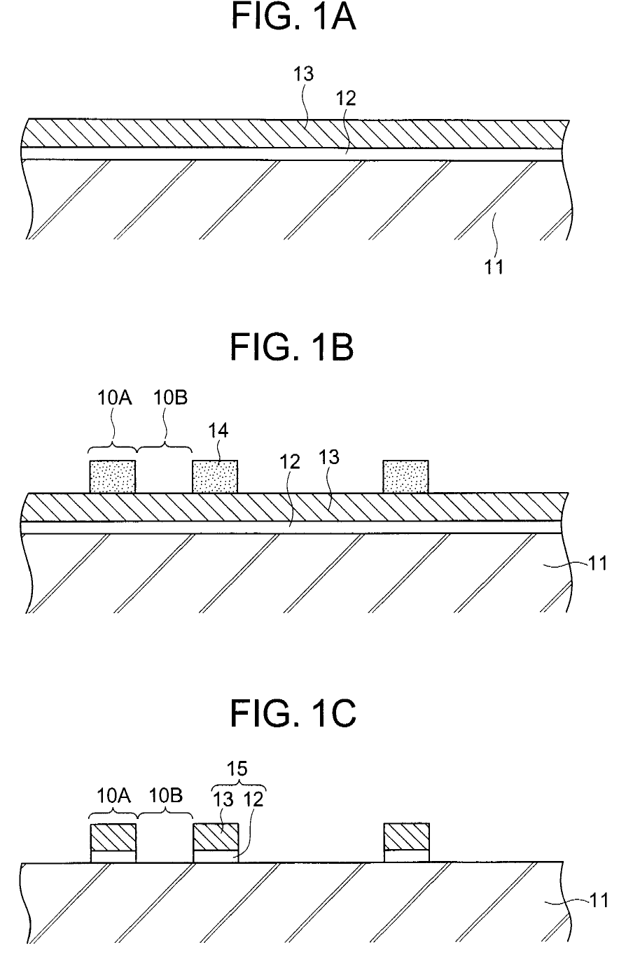

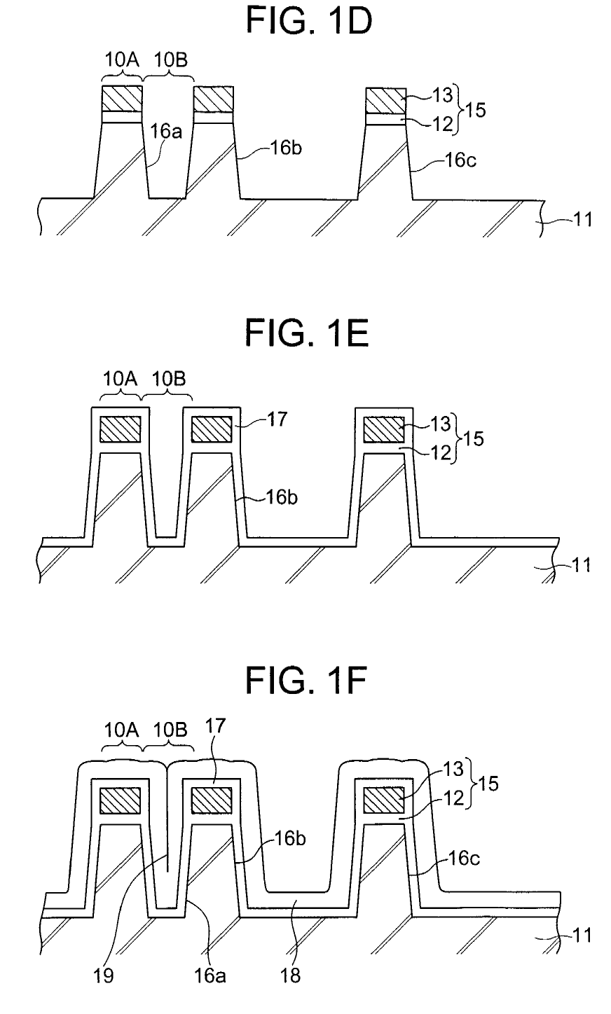

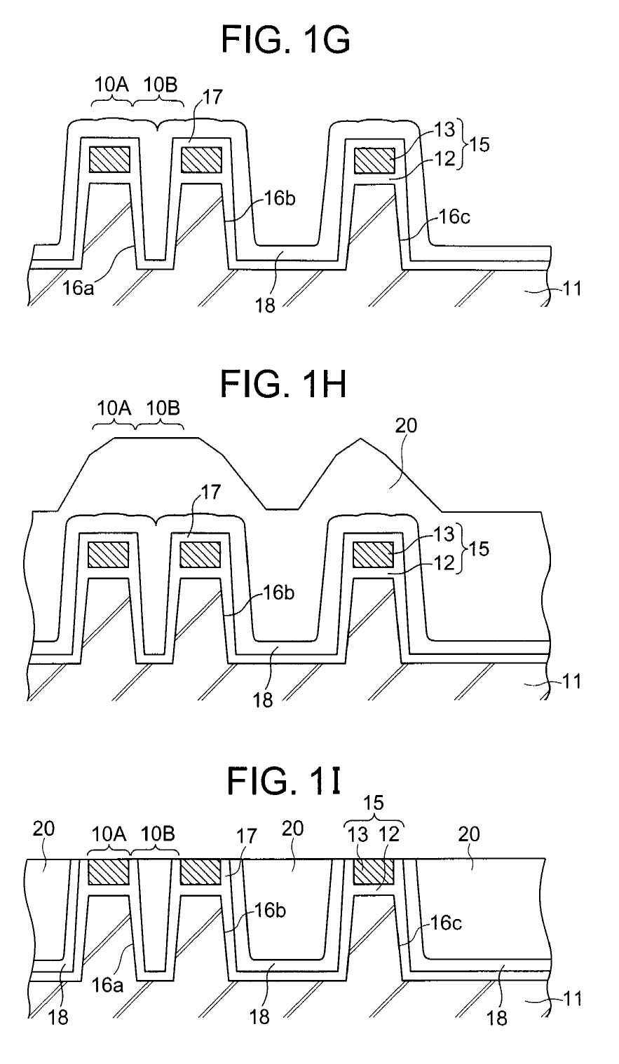

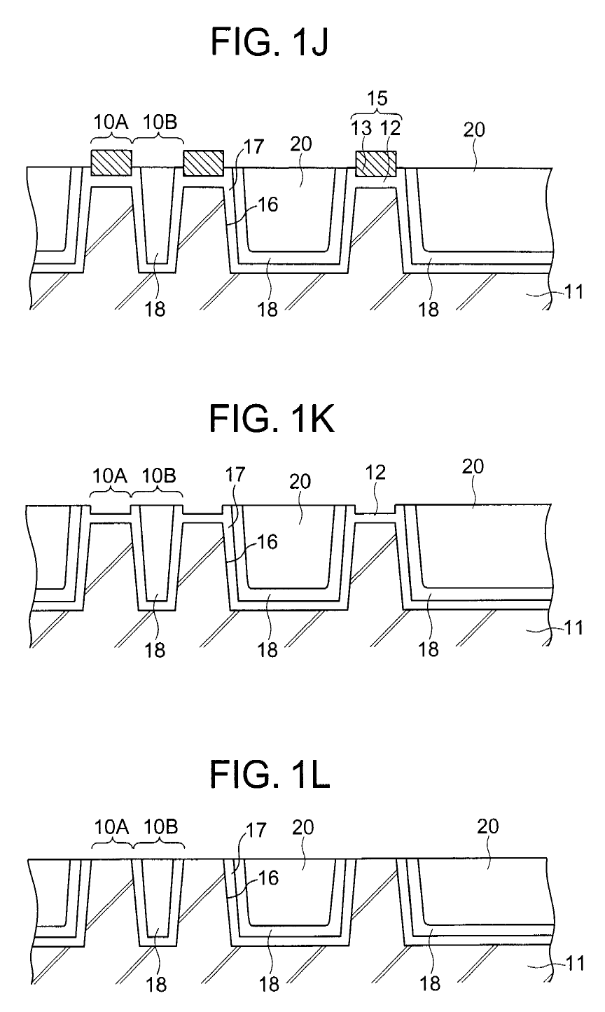

FIGS. 1A to 1L are sectional views of a semiconductor device, consecutively showing steps of a process for manufacturing the semiconductor device according to a first embodiment of the present invention. First, thermal oxidation is performed to form a silicon oxide film (thermally-oxidized film) 12 on the surface of a silicon substrate, or semiconductor substrate 11. Subsequently, a silicon nitride film 13 is deposited on the silicon oxide film 12 by using a is CVD process (FIG. 1A). A resist mask 14 is then formed on the silicon nitride film 13 (FIG. 1B). The resist mask 14 has a pattern of element formation regions 10A.

Using the resist mask 14 as an etching mask, dry etching is performed to pattern the silicon nitride film 13 and silicon oxide film 12, thereby forming therefrom a hard mask 15. The resist mask 14 remaining on the hard mask 15 is removed (FIG. 1C). Using the hard mask 15 as an etching mask, dry etching is performed to remove surface portions of the semiconductor substrate 11 and form isolation trenches 16a, 16b, 16c having a depth of 250 nm in isolation regions 10B (FIG. 1D).

Trench 16a has a smallest width of 80 nm, a minimum width that can be formed in the current patterning technology, such as the width for the memory cell area in a DRAM device. Trench 16b has an intermediate width of 250 nm, and trench 16c has a largest width of more than 250 nm, both the widths corresponding to the widths of the trench generally used in the peripheral area of the current DRAM device. The smallest-width trench 16a has a depth of 250 nm, as described above, and thus has an aspect ratio of more than 3.0, the aspect ratio being defined by a ratio of depth to width of the trench. That is, the trenches in the semiconductor device of the present embodiment include a trench having an aspect ratio of at least 3.0. To achieve a finer semiconductor element in the DRAM device, the aspect ratio will be larger due to a smaller required width.

Subsequently, thermal oxidation is performed to form a silicon oxide film (thermally-oxidized film) 17 on the entire surface including the internal of the isolation trenches 16a, 16b, 16c (FIG. 1E). Forming the thermally-oxidized film 17 can decrease the step difference between the surface of the semiconductor substrate 11 on which the semiconductor elements are to be formed and the bottom of the isolation trenches 16a, 16b, 16c.

A LP (Low Pressure)-CVD process is then used to deposit a silicon oxynitride film (SiON film) having a thickness of 50 to 100 nm and fill the internal of the isolation trenches (FIG. 1F). In this step, the smallest-width trench 16a is completely filled with the SiON film 18 whereas the intermediate-width and largest-width trenches 16b, 16c are not completely filled with the SiON film 18, as shown in FIG. 1F. In addition, it is to be noted that the deposition of SiON film 18 forms a seam 19 in the smallest-width trench 16a. The generation of seam may cause a short-circuit failure between gate electrodes of adjacent transistors, and thus is not preferable. On the other hand, the deposition of SiON film 18 after formation of the thermally-oxidized film 17 inside the isolation trenches 16a, 16b, 16c suppresses the stress generally caused by the deposited SiON film 18 from affecting the semiconductor substrate 11, thereby preventing deterioration in the characteristic of the semiconductor elements formed later.

Thereafter, heat treatment is performed in an oxidizing atmosphere so as to decrease the nitrogen concentration in the silicon oxynitride film 18. This heat treatment reduces the nitrogen concentration in the silicon oxynitride film 18 and, at the same time, increases the oxygen concentration whereby the film quality of the silicon nitride film approaches to that of the silicon oxide film. This results in a higher etch rate of the silicon oxynitride film 18, which desirably approximates to and becomes equivalent to the etch rate of the silicon oxide film. In addition, this thermally oxidizing treatment increases the volume of the silicon oxynitride film 18 to thereby extinguish the seam 19 in the smallest-width trench 16a (FIG. 1G).

Subsequently, a HDP-CVD process is used to deposit a silicon oxide film (HDP film) 20, as shown in FIG. 1H. Although the silicon oxynitride film 18 has a superior filling capability, it has a lower deposition rate as compared to the HDP film 20. Accordingly, deposition of the HDP film 20 after filling the internal of the smallest-width trench 16a with the silicon oxynitride film 18 provides a higher production efficiency. At this stage of deposition, the intermediate-width and largest-width trenches 16b, 16c are completely filled with the insulator material, without occurring of the seam therein due to the larger width of the trenches 16b, 16c. It is to be noted that the heat treatment for reducing the nitrogen concentration in the silicon oxynitride film 18 may be conducted after deposition of the HDP film 20. A CMP (Chemical Mechanical Polishing) process is then used for planarization to expose top of the silicon nitride film 13 (FIG. 1I).

Thereafter, a wet etching process is conducted using a hydrofluoric acid to remove the top portion of the above silicon-oxide-group films including the thermally-oxidized film 17, silicon oxynitride film 18 and HDP film 20 (FIG. 1J). Another wet etching process is then performed using a hot phosphoric acid, to remove the silicon nitride film 13 (FIG. 1K).

Thereafter; another etching process is conducted using a hydrofluoric acid to remove the top portion of the silicon-oxide-group films 12, 17, 18, and 20 to expose the surface of the semiconductor substrate 11. In this manner, the isolation structure is obtained in the isolation region 10B, the isolation structure being configured by the silicon oxynitride film 18 and HDP film 20, which are embedded in the isolation trenches 16a, 16b, 16c with an intervention of the thermally-oxidized film 17 (FIG. 1L). The series of wet etching processes shown in FIG. 1I and 1L equally controls the etch rate of the silicon oxynitride film 18, thermally-oxidized films 12, 17 and HDP film 20, thereby suppressing occurrence of the step difference at the boundary between the silicon oxynitride film 18 and the thermally-oxidized films 12, 17 and between the silicon oxynitride film 18 and the HDP film 20.

The wet etching processes shown in FIGS. 1J and 1L each may use an etching solution including hydrogen fluoride (HF) and ammonium fluoride (NH₄F) mixed at a ratio of 30:1, for example. The order of the wet etching processes in FIGS. 1J to 1L may be changed from the above embodiment. Instead of the series of etching processes used therein, a first wet etching process may be conducted to remove the silicon nitride film 13, and then a second wet etching process may be conducted to remove the silicon-oxide-group films 12, 17, 18, and 20.

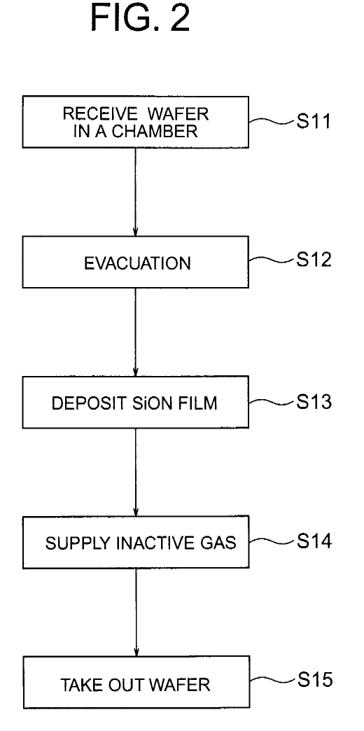

FIG. 2 is a flowchart showing the deposition step for the silicon oxynitride film 18 shown in FIG. 1F. A wafer (semiconductor substrate) 11 is received in a chamber of an LP-CVD system (Step S11). A known structure for the LP-CVD system may be used herein. The internal of the chamber is then evacuated (Step S12).

Source gases including N₂O, NH₃ and DCS (Dichlorosilane: SiH₂CL₂) are then introduced into the chamber in this order to deposit the silicon oxynitride film 18 (Step S13). Deposition of the silicon oxynitride film 18 uses a substrate temperature of 650 to 750 degrees C., an ambient pressure of 0.3 to 1.0 Pa, and a growth rate of 0.1 to 0.5 nm/min. The flow rates of N₂O, NH₃ and DCS are set at 100 to 800 sccm, 5 to 10 sccm, and 50 to 100 sccm, respectively.

At Step S13, the N₂O, NH₃ and DCS are introduced in the chamber in this order. This makes it possible to increase the growth rate up to a desired rate, and prevent a SiN-rich layer, which is likely to trap electric charge, from being formed beneath the deposited silicon oxynitride film 18. After the deposition of the silicon oxynitride film 18 is completed, supply of the source gases is stopped in the order of DCS, NH₃, and N₂O.

Inactive gas such as N₂ is then supplied into the chamber to purge the remaining gases from the chamber (Step S14). The pressure inside the chamber is then increased to the atmospheric pressure. Thereafter, the wafer 11 is taken out of the chamber (Step S15) to terminate the deposition process.

The above deposition process provided a silicon oxynitride film having a refractive index of 1.50 to 1.64 as measured immediately after the deposition, a composition ratio of 60 to 90% for the number of oxygen atoms to the total of oxygen and nitrogen atoms, and a composition ratio of 10 to 40% for the number of nitrogen atoms to the same total. An XPS apparatus (X-ray photoelectron spectrometer) was used to measure the composition ratio of these atoms.

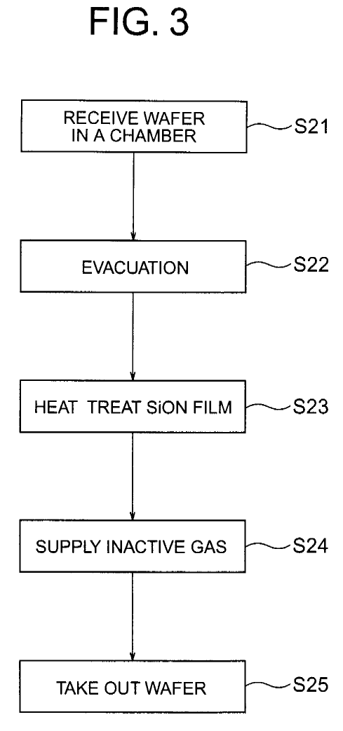

FIG. 3 is a flowchart showing the heat treatment step for the silicon oxynitride film 18 shown in FIG. 1G The wafer 11 is received in the chamber for heat treatment (Step S21). Before this step, the substrate temperature is set in advance at 300 degrees C., for example. The chamber is then evacuated vacuumed (Step S22).

A heat treatment is performed for ten minutes or longer in an oxidizing atmosphere containing H₂O at a volume ratio of 30% or more (Step S23), wherein the substrate temperature is set at 700 to 850 degrees C. According to the present embodiment, the substrate temperature is set at 750 degrees C., for example, and the time length is set at 60 minutes. The nitrogen concentration in the silicon oxynitride film 18 decreases down to a half or less of that before the heat treatment.

Thereafter, another heat treatment is performed for five minutes or longer in the N₂ atmosphere by setting the substrate temperature at 700 to 1100 degrees C., in order to further remove water from the furnace (Step S24). In this step of the present embodiment, the substrate temperature is set at 950 degrees C., for example, and the time length is set at 30 minutes. The pressure in the chamber is then increased to the atmospheric pressure. The wafer 11 is then taken out of the chamber (Step S25) to terminate the heat treatment.

The above heat treatment allows the etch rate for the silicon oxynitride film 18 to be set at 16 to 18.5 nm/minute, for the case where the etching uses hydrogen fluoride and ammonium fluoride mixed at a ratio of 30:1 in the etching solution. A similar condition provides an etch rate of 18 nm/minute for the thermally-oxidized films 12 and 17 and HDP film 20.

The heat treatment for the silicon oxynitride film 18 provides a control of the film quality thereof by measuring the refractive index of the silicon oxynitride film 18. Table 1 lists the film thickness and refractive index of the silicon oxynitride films 18, measured before and after the heat treatment of the silicon oxynitride film 18.

TABLE 1

| | Before heat treatment | After heat treatment |
|---|---|---|
| Average | 145.6 | 151.6 |
| film thickness (nm) | | |
| Minimum | 130.5 | 135.7 |
| film thickness (nm) | | |
| Maximum | 158.0 | 165.1 |
| film thickness (nm) | | |
| Range of variation | 9.4 | 9.7 |
| (%) | | |
| Increase in film | — | 6.0 |
| thickness (nm) | | |
| Average | 1.532 | 1.477 |
| refractive index | | |
| Minimum | 1.528 | 1.474 |
| refractive index | | |
| Maximum | 1.535 | 1.479 |
| refractive index | | |

In Table 1, the range of variation denotes a ratio of half the difference between the maximum film thickness and the minimum film thickness to the average film thickness. Table 1 reveals that the heat treatment decreases the average refractive index for the silicon oxynitride film 18 from 1.532 before the heat treatment to 1.477 after the same, and the film quality changes and approximates to that of silicon oxide. The refractive index for silicon nitride (SiN) ranges from 2.0 to 2.1, the refractive index of silicon oxynitride (SiON) ranges from 1.48 to 1.99, and the refractive index of silicon oxide (SiO₂) ranges from 1.46 to 1.47. Control of the film quality of the silicon oxynitride film 18 allows the etch rate thereof to be controlled.

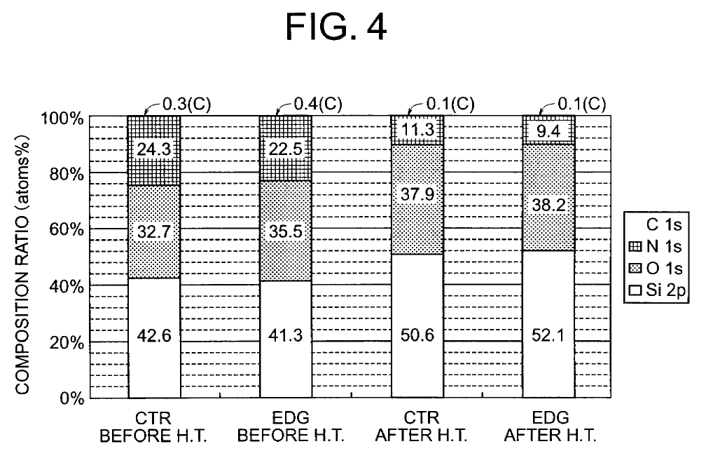

The film quality of the silicon oxynitride film 18 can be controlled by controlling the refractive index, as described above, and also controlled by controlling the composition ratio which may be analyzed using an XPS apparatus. FIG. 4 is a graph showing composition ratio of the silicon oxynitride film 18 measured using the XPS apparatus before and after the heat treatment (HT). In FIG. 4, CTR and EDG respectively indicate values measured at the center and the edge of the silicon oxynitride film 18. Observation of photoelectrons from the “1s orbit” allows the composition of carbon, nitrogen and oxygen atoms to be measured, whereas observation of photoelectrons from the “2p orbit” allows the composition of silicon atoms to be measured.

According to FIG. 4, the heat treatment decreases the composition ratio of nitrogen atoms in the silicon oxynitride film 18 from 24.3% before the heat treatment down to 11.3% after the heat treatment at the center of the silicon oxynitride film 18. The composition ratio also decreases from 22.5% before the heat treatment down to 9.4% after the heat treatment at the edge of the silicon oxynitride film 18. It will be understood that the heat treatment decreases the nitrogen concentration in the silicon oxynitride film down to half or less, and changes the film quality thereof to approximate to the film quality of silicon oxide.

The process for manufacturing the semiconductor device according to the present embodiment include the step of depositing the silicon oxynitride film 18 having an excellent filling property in the smallest-width isolation trench 16a, and performing a heat treatment to extinguish the seam in the trench 16a. This suppresses occurrence of voids in the smallest-width trench 16a.

The heat treatment after deposition of the silicon oxynitride film 18 decreases the nitrogen concentration in the silicon oxynitride film 18 down to half or less, and thus changes the film quality thereof so that it approximates to the film quality of a silicon oxide film. The present embodiment is especially effective to change the film quality of the silicon oxynitride film 18 so that the etch rate of the silicon oxynitride film 18 after the heat treatment exhibits an equivalence to the etch rate of the thermally-oxidized films 12 and 17 and HDP film 20. It is thus possible to suppress generation of the step difference at the boundary between the silicon oxynitride film 18 and the thermally-oxidized films 12, 17 and between the silicon oxynitride film 18 and the HDP film 20 during the wet etching step as shown in FIG. 1J or 1L.

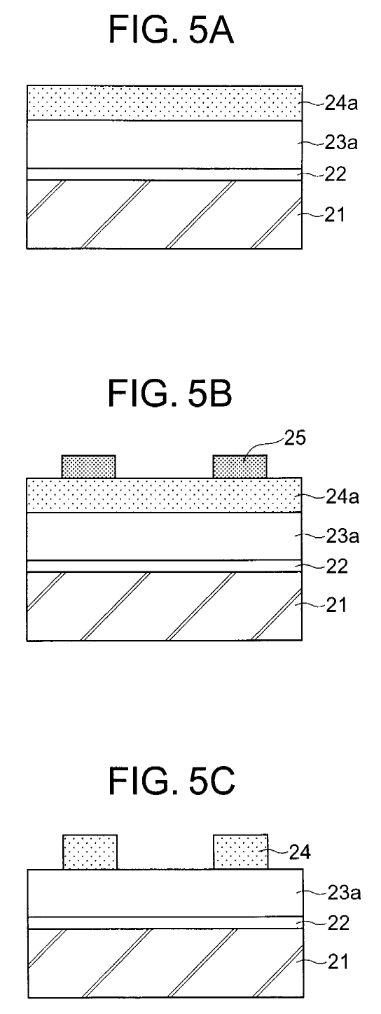

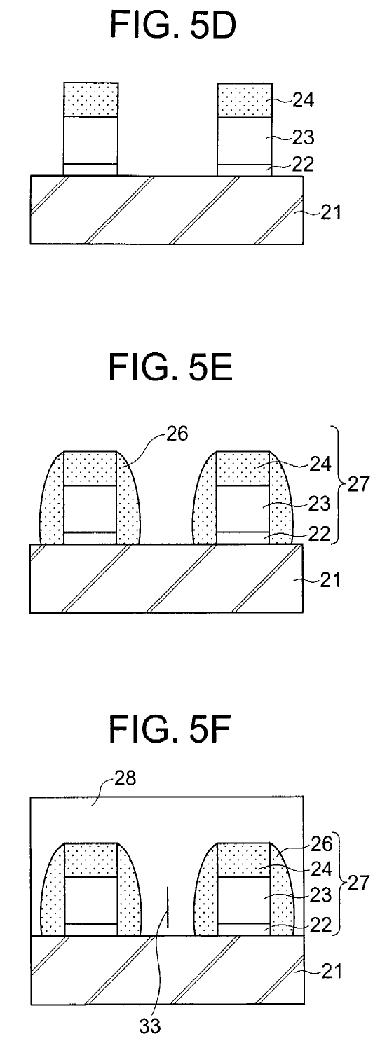

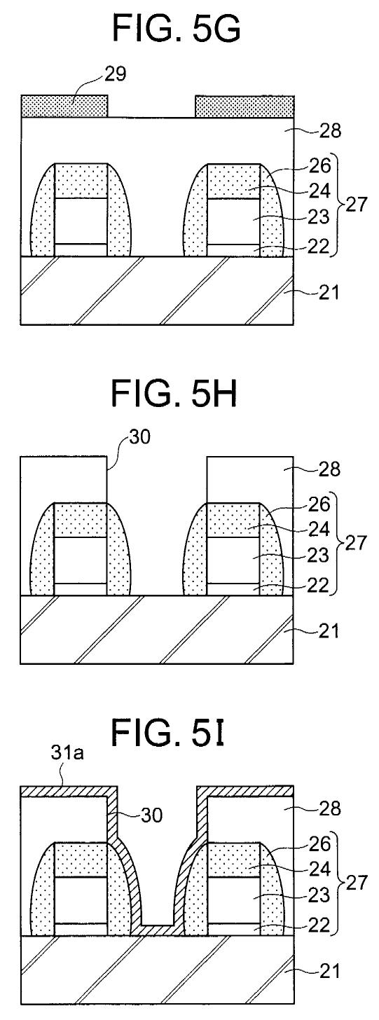

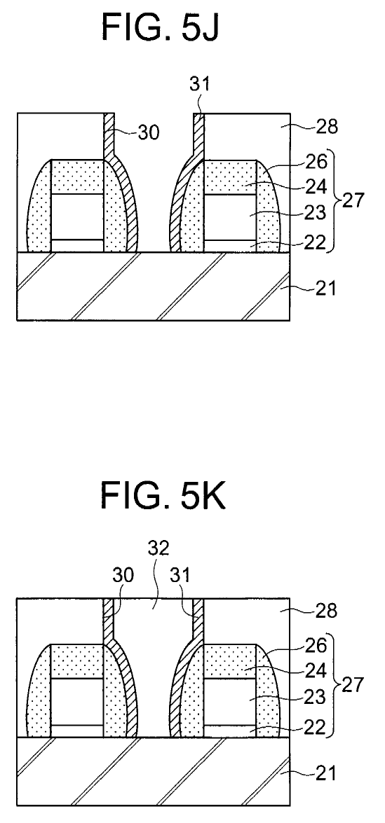

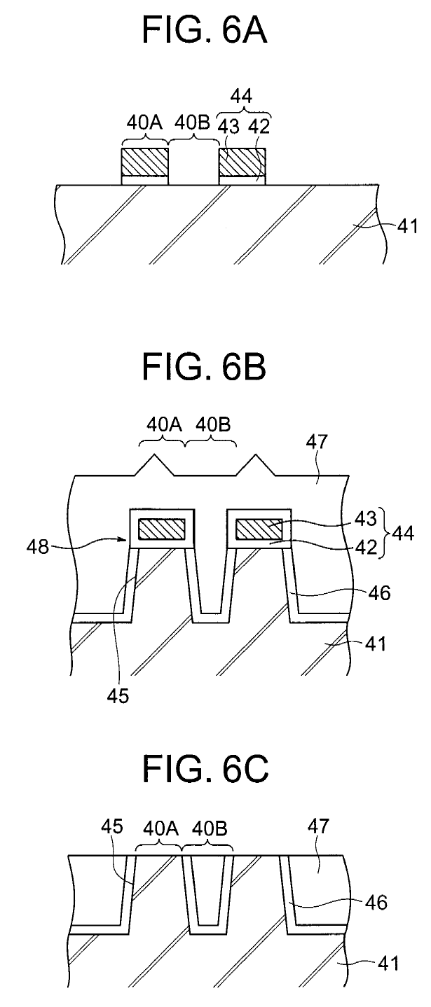

FIGS. 5A to 5K are sectional views of a semiconductor device, consecutively showing steps of a process for manufacturing the semiconductor according to a second embodiment of the present invention. The present embodiment is directed to an example of the process for forming contact plugs, and uses the silicon oxynitride film as an interlevel dielectric film that covers the gate electrode structure.

An ISSG (In-Situ Steam Generation) process is used to form a gate oxide film 22 on a semiconductor substrate 21. A PVD (Physical Vapor Deposition) process is then used to form a tungsten film 23a and a silicon nitride film (SiN film) 24a in this order on the gate oxide film 22 (FIG. 5A). A known photolithographic process is used to form a resist mask 25 having a gate electrode pattern on the silicon nitride film 24a (FIG. 5A).

A dry etching process is conducted using CF₄ as an etching gas and the resist mask 25 as an etching mask to pattern the silicon nitride film 24a, thereby forming therefrom a hard mask 24. The resist mask 25 remaining on the hard mask 24 is then removed (FIG. 5C). Another dry etching process is conducted using SF₆ as an etching gas and the hard mask 24 as an etching mask to pattern the tungsten film 23a and the gate oxide film 22 (FIG. 5D). The patterned tungsten film 23a configures interconnects, or gate electrodes, 23 which configure word lines in a DRAM device.

After deposition of a silicon nitride on the entire surface by using a CVD process, an etch-back process is conducted to form a sidewall film 26 that covers sides of the gate oxide film 22, interconnects 23, and hard mask 24 (FIG. 5E). In this manner, gate electrode structures 27 are obtained each including the gate oxide film 22, interconnect 23, hard mask 24, and sidewall film 26.

As an interlevel dielectric film, a silicon oxynitride film 28 is deposited on the entire surface to cover the gate electrode structures 27 (FIG. 5F). In this step, a seam 33 is generated in the central portion of the silicon oxynitride film 28 sandwiched between adjacent gate electrode structures 27. Thus, a heat treatment is performed to extinguish the seam 33. The deposition and heat treatment of the silicon oxynitride film 28 are conducted under the process conditions similar to those in the first embodiment.

A known photolithographic process is then conducted to form a resist mask 29 on the silicon oxynitride film 28 (FIG. 5G). A dry etching process is conducted using C₅F₈ as an etching gas and the resist mask 29 as an etching mask to pattern the silicon oxynitride film 28, thereby forming therein contact holes 30, which expose a surface portion of the semiconductor substrate 21 and the sidewall 26 of the gate electrode structures 27. The contact holes 30 are formed between adjacent gate electrode structures 27. The resist mask 29 remaining on top of the silicon oxynitride film 28 is then removed (FIG. 5H). A wet cleaning process is applied to the internal of the contact holes 30. The wet cleaning process uses an etching solution including hydrogen fluoride and ammonium fluoride mixed at a ratio of 30:1, for example.

A LP-CVD process is then used to deposit a silicon nitride film 31a on the bottom and sidewall of the contact holes 30 and on top of the silicon oxynitride film 28 (FIG. 5I). The deposition of the silicon nitride film 31a is performed at a substrate temperature of approximately 700 degrees C. An etch-back process is then conducted to remove a portion of the silicon nitride film 31a formed on the bottom of the contact holes 30 and on top of the silicon oxynitride film 28. The remaining portion of the silicon nitride film 31a formed on the sidewall of the contact holes 30 configures a sidewall protection film 31 (FIG. 5J).

A LP-CVD process is used to deposit a polysilicon film on the entire surface of the wafer including the internal of the contact holes 30. The polysilicon film deposited on top of the silicon oxynitride film 28 is then removed to leave contact plugs 32 (FIG. 5K).

Generally, interlevel dielectric films used in a conventional technique include a BPSG film deposited using a SA-CVD (Subatmospheric Pressure-CVD) process and a SOG film formed as a silicon oxide film by using a SOG (Silicon-On-Glass) coating process. The conventional interlevel dielectric films have a higher etch rate in an etching process using ammonia peroxide or hydrofluoric acid used as an etching solution during a wet cleaning process for cleaning the internal of the contact holes 30. Presence of the seams 33 accelerates the etch rate of a portion of the interlevel dielectric film adjacent to the seams 33, thereby causing occurrence of voids therein due to selective etching of the vicinity of the seams 33. The voids, which extend parallel to the gate electrode structures, i.e., normal to the sheet of the drawings, may receive therein a conductor material, which extends parallel to the gate electrode structures, during forming the contact plugs. Thus, the conductor material received in the voids may cause a short-circuit failure between adjacent two of the contact plugs.

On the other hand, in the process for manufacturing the semiconductor device according to the present embodiment, the silicon oxynitride film 28 used as the interlayer dielectric film suppresses the occurrence of the voids, because the seems 33 are extinguished from the silicon nitride film by using the heat treatment thereof. In addition, the silicon oxynitride film subjected to the heat treatment has a lower etch rate comparable to the etch rate of the silicon oxide film, thereby further suppressing occurrence of the voids. The etch rate of the silicon oxynitride film subjected to the heat treatment is around 1/10 of the etch rate of the conventional BPSG film or SOG film.

It is to be noted that the sidewall protective film covering the sidewall of the interlevel dielectric film is provided after forming the contact holes in the present embodiment, thereby suppressing the sidewall of the contact holes from being etched. In the conventional technique using the BPSG film or SOG film, since the BPSG film or SOG film generally includes therein voids having a larger size, the sidewall protective film, if formed therein, does not effectively protect the sidewall of the contact holes due to the voids having the larger size. The silicon oxynitride film in the present embodiment suppressing the occurrence of the voids allows the sidewall protective film to effectively protect the sidewall of the contact holes in the interlevel dielectric film. This results in suppression of the short-circuit failure between adjacent contact plugs.

As described above, the method of the present invention provides a suitable etching characteristic during etching the silicon oxynitride film, especially in the etching process for etching the same together with the silicon oxide film.

In summary of the above embodiments, the present invention may have the following aspects.

The depositing step for the silicon oxynitride film may use a LP-CVD process. In this case, an oxynitride film having a superior acid resistance and a superior film property will be deposited at a higher deposition rate.

The heat treating step may include measuring a composition ratio of the silicon oxynitride film and controlling an etch rate of the silicon oxynitride film during the etching step based on the measured composition ratio. In an alternative, the heat treating step may include measuring a refractive index of the silicon oxynitride film and controlling an etch rate of the silicon oxynitride film during the etching step based on the measured refractive index.

The method of the present invention may further include, before the depositing step, the steps of: forming at least one trench on a surface portion of the semiconductor substrate; and forming a thermally-oxidized film on a surface of the trench. The heat treatment reduces the difference in the etch rate between the silicon oxynitride film and the thermally-oxidized film, thereby preventing a step difference from occurring at the boundary between the silicon oxynitride film and the silicon oxide film.

In the above configuration, the thermally-oxidized film and the silicon oxynitride film may have substantially equal etch rate in the etching step. This prevents occurrence of the step difference more effectively. The trench may have a width of 80 nm or less, and an aspect ratio of 3.0 or above. Such a configuration of the trench is generally involved with a void in a silicon oxide film deposited in the trench even if a HDP-CVD process is used. The deposition of the silicon oxynitride film instead of the silicon oxide film effectively prevents the void from occurring in the silicon oxynitride film.

The method of the present invention may further include the step of depositing a film, e.g., a silicon oxide film, having a growth rate higher than the growth rate of the silicon oxynitride film between the silicon oxynitride film depositing step and the etching step. It is known that the growth rate of the silicon oxynitride film is relatively low. Thus, in this configuration, the lower part of the trench is filled with the silicon oxynitride film having a superior filling property. On the other hand, the upper part of the trench is filled with a film, e.g., silicon oxide film, having a higher growth rate, thereby improving the production efficiency. The lower part requiring the higher filling property may be an isolation trench having a minimum width in general. In this case, the heat treatment may be conducted before or after deposition of the film having the higher growth rate than the silicon oxynitride film.

In the method of the present invention, the etching step may form contact holes in an interlayer dielectric film made of silicon oxynitride. It is to be noted that contact plugs are generally formed after forming the contact holes in the interlayer dielectric film, that a void, if occurring in the interlayer dielectric film, will receive therein a conductor material during depositing the conductor material to form the contact plugs in the contact holes, and that the conductor material received in the void may cause a short-circuit failure between adjacent contact plugs. If the interlayer dielectric film is configured by the silicon oxynitride film which is subjected to the heat treatment, the occurrence of the void can be prevented to suppress the short-circuit failure.

The method of the present invention may include a wet cleaning step for cleaning the contact holes as described above. In the conventional technique, if a seam is formed in an interlayer dielectric film having a higher etch rate, the portion of the interlevel dielectric film adjacent to the seam will be selectively etched to generate the void. On the other hand, the interlevel dielectric film configured by the silicon oxynitride film which is subjected to the heat treatment can reduce the size of the seam itself, and reduces the etch rate of the vicinity of the seem to suppress occurrence of the voids in the interlevel dielectric film during the wet cleaning.

The method of the present invention is not limited to formation of the isolation structure as described in the first embodiment or formation of the interlevel dielectric film as described in the second embodiment, and can be applied to a variety of usages.

Since the above embodiments are described only for examples, the present invention is not limited to the above embodiments and various modifications or alterations can be easily made therefrom by those skilled in the art without departing from the scope of the present invention.

What is claimed is:

1. A method for forming a semiconductor device, comprising the steps of:
depositing a silicon oxynitride film overlying a semiconductor substrate;
heat treating said silicon oxynitride film in an oxidizing atmosphere; and
etching said silicon oxynitride film for patterning thereof after said heat treating.

2. The method according to claim 1, wherein said depositing step uses a low-pressure chemical vapor deposition process.

3. The method according to claim 1, wherein said heat treating step includes measuring a composition ratio of said silicon oxynitride film and controlling an etch rate of said silicon oxynitride film during said etching step based on said measured composition ratio.

4. The method according to claim 1, wherein said heat treating step includes measuring a refractive index of said silicon oxynitride film and controlling an etch rate of said silicon oxynitride film during said etching step treating based on said measured refractive index.

5. The method according to claim 1, further comprising, before said depositing step, the steps of:
forming at least one trench on a surface portion of said semiconductor substrate; and
forming a thermally-oxidized film on a surface of said trench.

6. The method according to claim 5, wherein said thermally oxidized said film and said silicon oxynitride film have substantially equal etch rate in said etching step.

7. The method according to claim 5, wherein said at least one trench includes a first trench having a width of 80 nm or less and an aspect ratio of 3.0 or above.

8. The method according to claim 1, wherein said etching step forms a through-hole in said silicon oxynitride film.

9. The method according to claim 8, further comprising the step of wet cleaning an internal of said through-hole.
